(19) United States
(12) Patent Application Publication
(10) Pub. No.: US 2026/0218809 A1
(43) Pub. Date: Jul. 30, 2026

(54) Proportional Vacuum Valve Apparatus

(71) Applicant: Parker Hannifin EMEA S.Á.R.L., Etoy (CH)

(72) Inventor: Alan J. Smith, Buckinghamshire (GB)

(21) Appl. No.: 19/147,502

(22) PCT Filed: Nov. 27, 2023
(86) PCT No.: PCT/EP2023/083235

§ 371 Date: Jul. 11, 2025

(30) Foreign Application Priority Data
Feb. 17, 2023 (GB) 2302264.3

(51) Int. Cl. F16K 31/365; F16K 51/02; H10P 72/78

(52) U.S. Cl. CPC F16K 31/365; F16K 51/02; H10P 72/78

(57) ABSTRACT

Proportional vacuum valve apparatus (100) has a vacuum supply port (112), a vacuum outlet port (106) in communication with the vacuum supply port (112), a valve seat (110), and a valve element (114) movable into and out of engagement with the valve seat (110) to close and open the valve permitting vacuum flow between the vacuum outlet port (106) and the vacuum supply port (112). A control arrangement is operable to open and close the valve. The control arrangement provides a proportional positive pressure supply to pilot operation of the valve element (114). The apparatus is particularly suited to being used in silicon wafer fabrication processes.

### FIELD OF INVENTION

The present invention relates to proportional vacuum valve apparatus.

### BACKGROUND

In certain technical fields there is a desire to provide proportional control of vacuum, for example, for clamping items. For example, the apparatus may be used for proportional control of vacuum for securing items to a securing surface such as clamping wafers onto a wafer table or other wafer handling device for one or more steps of a silicon chip manufacturing process. The apparatus may, for example, be part of a vacuum switching unit (which may be referred to as a clamp-free unit) that switches vacuum on and off for loading and unloading wafers and keeping the wafer in place during high-speed scanning or other handling processes. The clamp-free unit may be mounted inside the wafer table, and so beneficially, will be small and lightweight because it is required to be moved around at high speed.

Current clamp-free units known in the art, generally only contain on/off valves, not proportional. There are known proportional pressure controllers/regulators, (including vacuum controllers) that use solenoid valves to pilot a diaphragm operated flow valve, but these tend to be too large to fit into the wafer table space constraints. Example off-the-shelf controllers are Parker EPP4, SMC ITV & Festo VPP. Direct acting proportional solenoid valves might be considered an alternative, but they all have much smaller flow rates than required, or if made larger, would generate too much heat for this very temperature sensitive environment.

There is a requirement to process increasingly warped wafers (which is caused by the 3DNAND vertical stacking of memory on a chip). This makes it increasingly difficult to clamp wafers with vacuum because of the greatly increased vacuum leakage around the edge of the wafer. To help with this, it would be beneficial to use a proportional vacuum valve with much larger flow capability than before. This valve must be very small, lightweight, fast response, with life expectancy exceeding 40 to 50 million cycles.

The desire is therefore to provide a high flow rate, miniature, light-weight, long life proportional valve apparatus suitable for uses in restricted size environments that does not create significant heat in temperature sensitive environments.

Whilst the invention will primarily be described in relation to use for a clamp-free wafer table unit or other wafer handling apparatus, it will be readily appreciated that the valve apparatus is suitable for use in other applications requiring proportional control of vacuum, particularly in restricted size environments and temperature sensitive environments.

### SUMMARY

According to the present disclosure there is provided a proportional vacuum valve apparatus as described in the accompanying claims.

According to one aspect the invention provides a proportional vacuum valve apparatus, comprising:
a vacuum supply port;
a vacuum outlet port in communication with the vacuum supply port;
a valve seat;
a valve element movable into and out of engagement with the valve seat to close and open the valve permitting vacuum flow between the vacuum outlet port and the vacuum supply port; and a control arrangement operable to open and close the valve;
wherein the control arrangement comprises a proportional positive pressure supply to pilot operation of the valve element.

According to an aspect the invention provides a method of controlling a vacuum valve comprising: a vacuum supply port; a vacuum outlet port in communication with the vacuum supply port and a valve seat; a valve element being movable into and out of engagement with the valve seat to close and open the valve permitting vacuum flow between the vacuum outlet port and the vacuum supply port; wherein a proportional positive pressure gas supply is used to pilot operation of the valve element.

### BRIEF DESCRIPTION OF THE DRAWINGS

The invention will be further described in a specific embodiment, by way of example only, and with reference to the accompanying drawings, in which:

FIG. 1 is a schematic view of a high flow proportional vacuum valve according to an embodiment of the invention.

### DESCRIPTION OF EMBODIMENTS

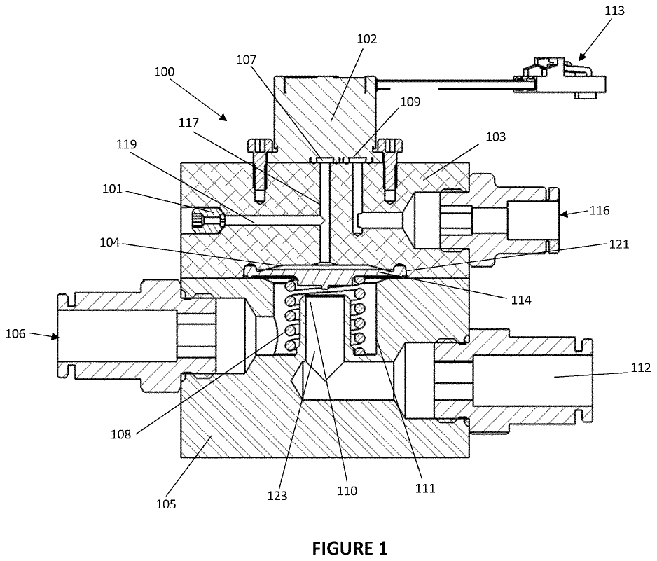

Referring to FIG. 1, there is shown a high flow proportional vacuum valve apparatus 100 which comprises an upper valve body 103 and a lower valve body 105. Mounted to the upper valve body is an electrically operated solenoid valve 102. The upper valve body has a compressed gas inlet port 116 which is connected to a pneumatic pressure source (not shown). The inlet port 116 directs positive pressure gas to the pneumatic inlet port 109 of the electrically operated solenoid valve 102. Operation of the solenoid valve 102 is controlled by a control device (not shown) via control wires 113. The outlet port 107 of the solenoid valve is connected to a passageway 117 that communicates with a pilot air cavity 104 immediately adjacently above a diaphragm 114. A further passageway 119 communicates between passageway 117 and a pilot bleed orifice 101.

The diaphragm 114 is secured in the upper valve body 103 by being located in an annular peripheral groove of the upper valve body. The diaphragm 114 is provided with a peripheral circular projection for this purpose. The upper valve body 103 can be considered a positive pressure circuit, because positive pressure is provided from the pressure port 116 to the pilot air cavity 104 controlled by the solenoid valve 102.

The lower valve body 105 is provided with a vacuum supply port 112 connected to a vacuum source (not shown). A proportional vacuum outlet port 106 is provided for the lower valve body 105 and when the valve is in an open condition, is connected to the vacuum supply port 112. In the open condition (as shown in FIG. 1) the valve operates such that vacuum is drawn via the outlet port 106 communicating with a chamber 111, through an open end 110 of a tube 123. Tube 123 communicates with the vacuum supply port 112. A helical spring 108 is provided in the chamber 111, extending about the tube 123. In the open condition of the valve the spring urges the diaphragm 114 away from seated engagement with a seat formed by the open end 110 of the tube 123 such that vacuum may be drawn into the cavity 104. In the closed condition of the valve, the positive pressure in the pilot air cavity 104 forces the diaphragm to compress the spring 108 and to seat with the valve seat formed by the open end 110 of the tube 123, thereby preventing vacuum being drawn through the open end 110 of the tube 123. The diaphragm 114 is secured at its peripheral edge, and a central portion spaced from the peripheral edge is arranged to flex into and out of engagement with the valve seat.

To overcome the short life expectancy of small conventional diaphragms, such as fabric reinforced flexible rolling or convoluted diaphragms, that suffer significant strain of the fabric during operation, a small diameter, relatively thick, flat, plastic or rubber diaphragm 114 is used where less strain occurs during operation. This diaphragm is stiffer than the conventional diaphragms, and requires relatively large forces to open and close the flow valve due to the stiffness of the diaphragm. This requires a high spring force.

In order to overcome the necessary high spring force of the helical spring 108, positive pressure is used to pilot the diaphragm 114, against the strong spring force of the helical spring 108 to close it. Pressures in the range 2 to 3 bar are typical to close the valve. The use of positive pressure to control a vacuum output is important in this context because it enables the high forces to be achieved. The relatively large forces that this positive pressure creates can overcome the diaphragm stiffness, creep during its life, and the stiffness of the closing spring. The relative incompressibility of the compressed air in the pilot (compared to vacuum) means that the position of the diaphragm, and therefore opening of the valve, are relatively unaffected by variations in supply pressure and flow, and variations between spring 108 and diaphragm 114 stiffness. The simplicity of the design yields other benefits such as good reliability, minimal friction and low cost.

The pilot air positive pressure can be controlled by a proportional valve orifice in the electrically operated solenoid valve 102 (as is conventional and well known in the art) and the pilot bleed orifice 101. The positive pressure at the pilot air cavity 104 acts on the top of the diaphragm 114, pushing it down. This is balanced by the upwards force of the spring 108 on the diaphragm 114. As the pilot pressure at the pilot air cavity 104 is varied, the diaphragm 114 moves up/down, to control the flow valve opening, which is the gap between the diaphragm 114 and the flow valve seat 110. With the use of PID pressure feedback control, this can be used to control the pressure on the proportional vacuum output.

A problem solved by the invention is that of fitting what is normally be required to be a large controller/valve into a small space. Also, the requirement for >50 million cycles life expectancy and low heat output. The convoluted, fabric reinforced, rubber diaphragms used in prior art controllers are unsuitable for use in lightweight, small size/space envelope scenarios because they have to stretch more than for larger diaphragms, which reduces their life expectancy. If a small piston were used instead, the friction would severely hinder controller accuracy and responsiveness.

Typically, the space envelope available is of the order of 25 mm×25 mm×45 mm and the overall weight of the valve assembly is of the order of 60 g.

The apparatus has been described using a pilot operated proportional/variable solenoid valve. It should be appreciated that whilst this may be a preferred option, other piloting solutions are possible. For example, a piezo actuator with bleed may be used, or a pair of on/off solenoid valves may be used. Also, a Micro Electro Mechanical System (MEMS) valve could be used. All provide proportional positive pressure supply to pilot operation of the valve element (diaphragm 114).

The valve apparatus 100 of the present invention can be mounted or otherwise connected to a wafer table for example for one or more process steps of a silicon chip manufacturing process. The valve apparatus 100 may, for example, be part of a clamp-free unit that switches vacuum on and off for loading and unloading wafers and keeping the wafer in place during high-speed operations in the manufacturing process The clamp-free unit may be mounted inside the wafer handling device, is small and lightweight because it is required to be moved around at high speed.

With respect to the valve apparatus 100 described in relation to FIG. 1, the apparatus can be generalised as proportional vacuum valve apparatus, comprising a vacuum supply port 112; a vacuum outlet port 106 in communication with the vacuum supply port 102; a valve seat (exemplified by open end 110 of tube 123); a valve element (exemplified by diaphragm 114) movable into and out of engagement with the valve seat to close and open the valve permitting proportional vacuum flow between the vacuum outlet port and the vacuum supply port; and a control arrangement (exemplified by proportional solenoid valve 102) operable to open and close the valve; wherein the control arrangement comprises a proportional positive pressure pneumatic supply to pilot operation of the valve element (for example at pilot cavity 104).

The valve apparatus may include a biasing element (exemplified by spring 108), acting to bias the valve element to the open position, away from the valve seat. The biasing element may comprise a spring acting directly on the valve element.

The control arrangement may comprise a compressed gas supply to pilot operation of the valve element.

The proportional positive pressure supply may act directly on the valve element.

The valve element may comprise a flexible diaphragm. The flexible diaphragm may comprise a plastics or rubber material. The flexible diaphragm may be relatively thick and/or relatively stiff. The flexible diaphragm is preferably configured such that it does not experience significant strain during operation of the valve. The diaphragm may be secured at its peripheral edge, and a central portion spaced from the peripheral edge may be arranged to flex into and out of engagement with the valve seat.

The control arrangement may comprise a compressed gas supply to pilot operation of the valve element; and the compressed gas is ported to the pilot gas cavity 104 directly adjacent the valve element.

The control arrangement may comprise a solenoid valve arrangement 102 which is operated to provide a compressed gas supply to pilot operation of the valve element.

The control arrangement may comprise a proportional solenoid valve 102 to supply proportional pressure compressed gas to pilot operation of the valve element.

The control arrangement may be provided with a compressed gas inlet port.

1. A proportional vacuum valve apparatus, comprising:
a vacuum supply port;
a vacuum outlet port in communication with the vacuum supply port;
a valve seat;
a valve element movable into and out of engagement with the valve seat to close and open the proportional vacuum valve apparatus permitting vacuum flow between the vacuum outlet port and the vacuum supply port; and
a control arrangement operable to open and close the proportional vacuum valve apparatus;
wherein the control arrangement comprises a proportional positive pressure supply for pilot operation of the valve element.

2. The proportional vacuum valve apparatus of claim 1, wherein the proportional vacuum valve apparatus further includes a biasing element, acting to bias the valve element to an open position, away from the valve seat.

3. The proportional vacuum valve apparatus of claim 2 wherein the biasing element comprises a resilient biasing element such as a spring.

4. The proportional vacuum valve apparatus of claim 3, wherein the biasing element comprises a spring acting directly on the valve element.

5. The proportional vacuum valve apparatus of claim 1, wherein the control arrangement comprises a compressed gas supply for pilot operation of the valve element.

6. The proportional vacuum valve apparatus of claim 1, wherein the proportional positive pressure supply acts directly on the valve element.

7. The proportional vacuum valve apparatus of claim 1, wherein the valve element comprises a flexible diaphragm.

8. The proportional vacuum valve apparatus of claim 7, wherein the flexible diaphragm comprises a plastics or rubber material.

9. The proportional vacuum valve apparatus according to of claim 7, wherein the flexible diaphragm is configured such that the flexible diaphragm does not experience significant strain during operation of the proportional vacuum valve apparatus.

10. The proportional vacuum valve apparatus of claim 7, wherein the flexible diaphragm is secured at a peripheral edge of the flexible diaphragm, and wherein a central portion spaced from the peripheral edge is arranged to flex into and out of engagement with the valve seat.

11. The proportional vacuum valve apparatus of claim 1, wherein the control arrangement comprises;
a compressed gas supply for pilot operation of the valve element, wherein compressed gas from the compressed gas supply is ported to a pilot gas cavity directly adjacent the valve element.

12. The proportional vacuum valve apparatus of claim 1, wherein the control arrangement comprises one or more of a solenoid valve arrangement, a piezo actuator or a MEMS valve, which is operated to provide a compressed gas supply for pilot operation of the valve element.

13. The proportional vacuum valve apparatus of claim 12, wherein the control arrangement supplies proportional pressure compressed gas for pilot operation of the valve element.

14. The proportional vacuum valve apparatus of claim 12, wherein the control arrangement is provided with a compressed gas inlet port.

15. A method of controlling a vacuum valve comprising a vacuum supply port, a vacuum outlet port in communication with the vacuum supply port and a valve seat, and a valve element being movable into and out of engagement with the valve seat to close and open the vacuum valve permitting vacuum flow between the vacuum outlet port and the vacuum supply port, wherein the method comprises:
using a proportional positive pressure gas supply for pilot operation of the valve element.

16. A wafer fabrication or handling apparatus for a silicon chip manufacturing process, the wafer fabrication or handling apparatus including a proportional vacuum valve apparatus comprising:
a vacuum supply port;
a vacuum outlet port in communication with the vacuum supply port;
a valve seat;
a valve element movable into and out of engagement with the valve seat to close and open the proportional vacuum valve apparatus permitting vacuum flow between the vacuum outlet port and the vacuum supply port; and
a control arrangement operable to open and close the proportional vacuum valve apparatus;
wherein the control arrangement comprises a proportional positive pressure supply for pilot operation of the valve element.

17. (canceled)
